(19) United States
(12) Patent Application Publication
(10) Pub. No.: US 2026/0349172 A1
(43) Pub. Date: Nov. 5, 2026

(54) PHOTONIC PACKAGES AND METHOD OF FORMING THE SAME

(71) Applicant: Taiwan Semiconductor Manufacturing Co., Ltd., Hsinchu (TW)

(72) Inventor: Ming-Fa Chen, Taichung City (TW)

(21) Appl. No.: 19/272,310

(22) Filed: Jul. 17, 2025

Related U.S. Application Data
(60) Provisional application No. 63/797,227, filed on Apr. 30, 2025.

(51) Int. Cl. G02B 6/124; G02B 6/12; G02B 6/13; H10W 70/60; H10W 70/65; H10W 90/00; H10W 80/00

(52) U.S. Cl. CPC G02B 6/124; G02B 6/12004; G02B 6/13; H10W 70/611; H10W 70/65; H10W 90/00; G02B 2006/12102; G02B 2006/12107; H10W 80/312; H10W 80/327; H10W 90/794

(57) ABSTRACT

A method includes forming a first grating coupler and a second grating coupler in a first dielectric layer, wherein the first grating coupler is configured to couple optical signals of a first wavelength and the second grating coupler is configured to couple optical signals of a second wavelength; forming a bonding structure over a first side of the first dielectric layer; bonding an electronic die to the bonding structure; and forming a redistribution structure over a second side of the first dielectric layer, wherein the redistribution structure includes first conductive features; a first reflector overlapping the first grating coupler; and a second reflector overlapping the second grating coupler.

### PRIORITY CLAIM AND CROSS-REFERENCE

This application claims the benefit of U.S. Provisional Application No. 63/797,227, filed on Apr. 30, 2025, which application is hereby incorporated herein by reference.

### BACKGROUND

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) components and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, 9, 10, 11, 12 and 13, illustrate intermediate steps in the formation of an optical engine, in accordance with some embodiments.

FIG. 14 illustrates a magnified view of an optical engine, in accordance with some embodiments.

FIG. 15 illustrates a schematic of an optical engine in a perspective view, in accordance with some embodiments.

FIGS. 16, 17, 18, 19 and 20, illustrate intermediate steps in the formation of an optical engine, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various structures such as packages comprising photonic structures or the like and their methods of formation are described herein. Multiple grating couplers associated with optical signals of different wavelengths can be formed in a photonic package such as an optical engine. Each grating coupler may have an associated reflector that improves optical coupling into the grating coupler. Additionally, each reflector may be a different distance from its grating coupler, with the distance determined by the wavelength for which its grating coupler is configured. Forming reflectors at different distances allows the photonic package to compensate for the different speeds of different wavelengths of light.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

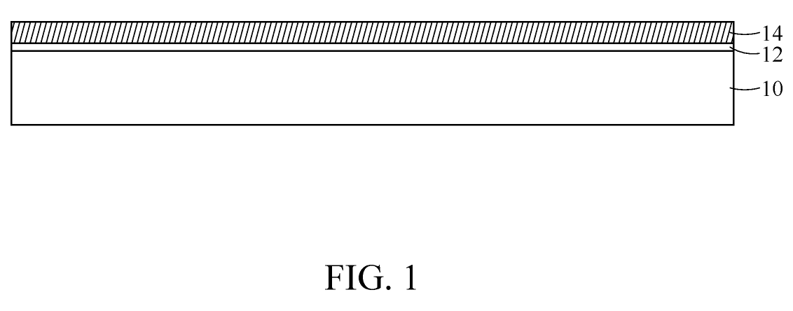

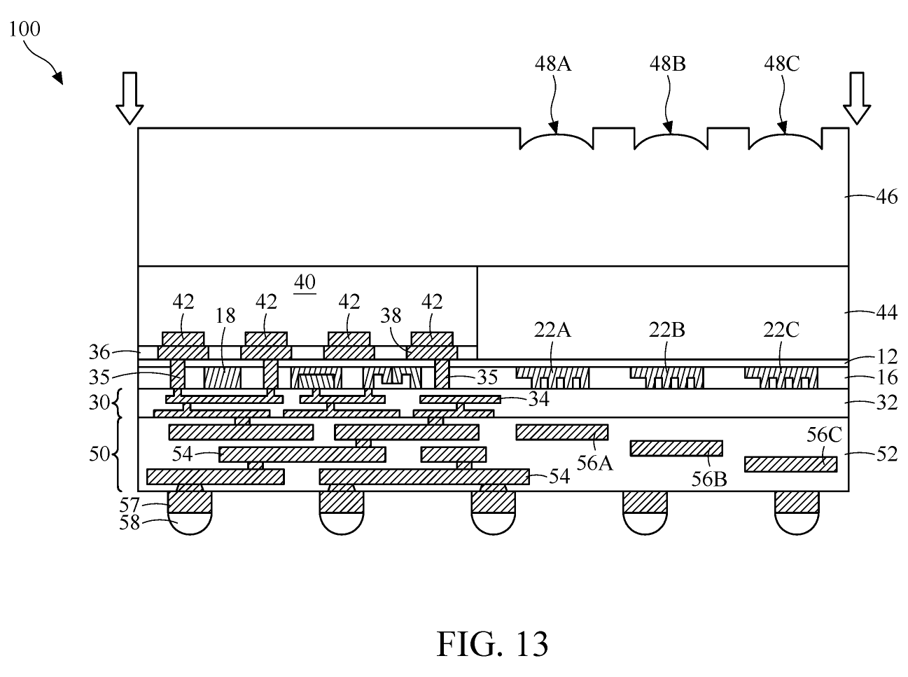

FIGS. 1 through 13 illustrate intermediate steps in the formation of an optical engine 100 (see FIG. 13), in accordance with some embodiments. The optical engine 100 comprises waveguides, photonic components, and integrated circuits that may be configured to receive, generate, modify, transmit, and/or process optical signals. In some embodiments, the optical engine 100 provides an input/output (I/O) interface between optical signals and electrical signals in a package or package component. In some embodiments, the optical engine 100 provides an optical network for signal communication between various components (e.g., photonic devices, integrated circuits, couplings to external fibers, etc.). In this manner, the optical engine 100 can enable optical-electrical (OE) conversion for package-level optical communication (e.g., within a package) and/or for optical communication with external components (e.g., via optical fiber(s)). In some cases, the optical engine 100 may be considered a photonic package, an optical package, a silicon photonic chip, a photonic die, a photonic semiconductor package, or the like.

Turning to FIG. 1, the optical engine 100 comprises at this stage a substrate 10, a dielectric layer 12, and photonic material 14, in accordance with some embodiments. In an embodiment, at a beginning of the manufacturing process of the optical engine 100, the substrate 10, the dielectric layer 12, and the photonic material 14 may collectively be part of a silicon-on-insulator (SOI) substrate or the like, which may be doped (e.g., with a p-type or an n-type dopant) or undoped. In some embodiments, the substrate 10 may be a wafer, such as a silicon wafer. Other substrates, such as a silicon-on-insulator (SOI) substrate, a multi-layered substrate, or a gradient substrate may also be used. In some embodiments, the semiconductor material of the substrate 10 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In other embodiments, the substrate 10 may be a dielectric material such as silicon oxide, glass, ceramic, plastic, or any other suitable material that allows for structural support of overlying devices. Other substrates, such as a multi-layered or gradient substrate, may also be used. The substrate 10 may be free of passive or active devices, in some cases. In some embodiments, multiple optical engines 100 are formed on a single substrate 10 and then are subsequently singulated into individual optical engines 100.

The dielectric layer 12 may be a dielectric layer that separates the substrate 10 from the overlying photonic material 14. In some embodiments, the dielectric layer can also serve as a portion of cladding material that surrounds the subsequently manufactured photonic components (described below). In an embodiment, the dielectric layer 12 may be silicon oxide, silicon nitride, germanium oxide, germanium nitride, the like, or a combination thereof. The dielectric layer 12 may be formed using a technique such as implantation (e.g., to form a buried oxide (BOX) layer) or using a suitable deposition technique such as chemical vapor deposition (CVD), atomic layer deposition (ALD), physical vapor deposition (PVD), combinations of these, or the like. However, any suitable material and method of manufacture may be used.

The photonic material 14 is formed over the dielectric layer 12. In some embodiments, the photonic material 14 may be a semiconductor material such as silicon, germanium, silicon germanium, a III-V semiconductor material, a compound semiconductor material, the like, or a combination thereof. In other embodiments, the photonic material 14 may comprise a dielectric material such as silicon nitride or the like, lithium niobate materials, polymers, the like, or a combination thereof. The photonic material 14 may be formed using a suitable technique, such as epitaxial growth, CVD, ALD, PVD, the like, or combinations thereof. Other materials or techniques are possible. In some cases, the photonic material 14 may be considered an “active layer” or the like.

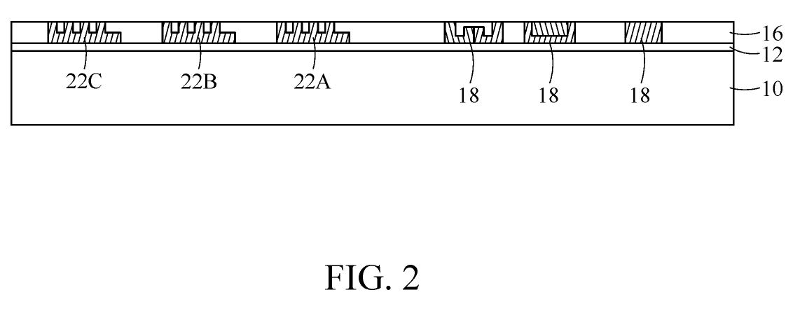

FIG. 2 illustrates the formation of photonic components 18 from the photonic material 14, in accordance with some embodiments. In some embodiments, the photonic components 18 may include such devices or components as optical waveguides (e.g., ridge waveguides, rib waveguides, buried channel waveguides, diffused waveguides, etc.), couplers (e.g., grating couplers 22, edge couplers, evanescent couplers, etc.), directional couplers, optical modulators (e.g., germanium modulators, Mach-Zehnder silicon-photonic switches, microelectromechanical switches, micro-ring resonators, etc.), amplifiers, multiplexors, demultiplexors, optical-to-electrical converters (e.g., photodetectors, P-N junctions, or the like), electrical-to-optical converters, lasers (e.g., laser diodes), phase shifters, combinations of these, or the like. However, the photonic components 18 may comprise other devices, structures, or components than these examples.

FIG. 2 illustrates various photonic components 18 including multiple grating couplers 22A-C. As described in greater detail below, each grating coupler 22A-C may be configured for optical signals of a different wavelength or range of wavelengths. Additionally, each grating coupler 22A-C may be optically coupled to a respective waveguide or other photonic component 18. A grating coupler 22A-C may be continuous with or adjacent to a photonic component 18 (e.g., a waveguide) to which it is optically coupled. For example, a waveguide may be optically coupled to an adjacent grating coupler 22, such that optical signals may be transmitted between the waveguide and the grating coupler 22. A grating coupler 22 may also be configured to receive optical signals from or transmit optical signals to an overlying photonic component such as an optical fiber or the like. In some cases, a waveguide and a grating coupler 22 may be portions of a continuous structure formed from the photonic material 14. Other numbers, arrangements, or configurations of grating couplers 22 are possible. Other numbers, arrangements, configurations, or types of photonic components 18 are possible.

In some embodiments, the photonic components 18 may be formed by patterning the photonic material 14 into the appropriate shapes for the photonic components 18. For example, photonic material 14 may be patterned using one or more photolithographic masking and etching processes, though any suitable methods of patterning the photonic material 14 may be utilized. The patterning may expose portions of the dielectric layer 12. In some cases, additional processing steps may be performed to form some types of photonic components 18, such as additional implantation processes, deposition processes, epitaxial growth processes, and/or patterning processes. In some embodiments, one or more photonic components 18 may be formed by patterning the photonic material 14 and then depositing another material on portions of the patterned photonic material 14. For example, the formation of a photonic component 18 may comprise patterning a photonic material 14 comprising silicon and then epitaxially growing a region of germanium on the patterned photonic material 14. In some cases, a grating coupler 22 may be formed by forming a structure having a periodicity of refractive index in a lateral (e.g., horizontal) direction. The periodic structure within a grating coupler 22 may be formed from the photonic material 14 and/or the dielectric layer 16 (described below), in some cases. In some cases, a grating coupler 22 may be configured for a particular wavelength or range of wavelengths by forming a periodic structure having a particular periodicity within the grating coupler 22. Grating couplers 22 and other photonic components 18 may be formed using other materials or techniques than described above.

Still referring to FIG. 2, a dielectric layer 16 may be formed over the dielectric layer 12 and/or the photonic components 18, in accordance with some embodiments. The dielectric layer 16 may be, for example, a dielectric material that separates the individual photonic components 18 from each other and from the overlying structures. Further, in some cases, the dielectric layer 16 can serve as a cladding material that at least partially surrounds and/or covers one or more photonic components 18. In some embodiments, the dielectric layer 16 may comprise silicon oxide, silicon nitride, germanium oxide, germanium nitride, combinations of these, or the like, which may be formed using suitable deposition techniques such as CVD, ALD, PVD, or the like. Other materials or deposition techniques are possible. In some embodiments, after depositing the dielectric layer 16, a planarization process (e.g., a chemical mechanical polishing (CMP) process, a grinding process, or the like) may be performed to planarize a top surface of the dielectric layer 16. In some embodiments, the planarization process may expose a top surface of one or more photonic components 18. In such embodiments, top surfaces of some photonic components 18 and top surfaces of the dielectric layer 16 may be level or coplanar (within process variations). In some embodiments, one or more photonic components 18 remain covered by the dielectric layer 16 after performing the planarization process. In some cases, the photonic components 18 and the dielectric layer 16 may collectively be considered a “photonic layer,” an “optical layer,” or the like.

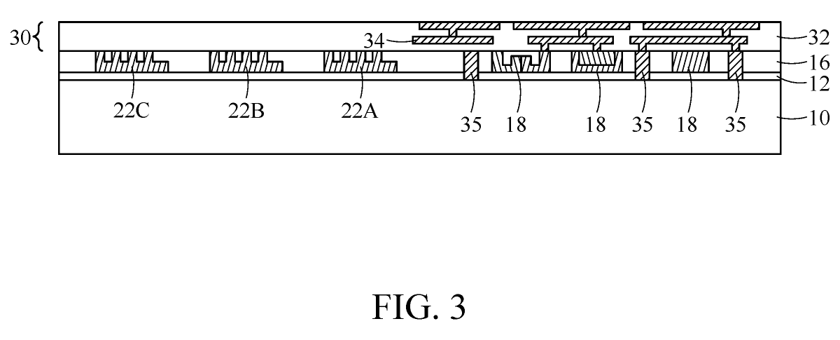

FIG. 3 illustrates the formation of an interconnect structure 30 over the dielectric layer 16, in accordance with some embodiments. In some embodiments, vias 35 are formed extending through the dielectric layer 16 and the dielectric layer 12 before forming the interconnect structure 30. In some embodiments, the vias 35 may be formed by first forming openings (not separately illustrated) in the dielectric layer 16 and the dielectric layer 12. In some cases, the openings may extend into the substrate 10. After forming the openings, an optional liner may be deposited in the openings, and then a conductive material may be deposited in the openings. The conductive material may be similar to those described for the conductive features 34 below. This is an example, and the vias 35 may be formed using other materials, techniques, or process steps. The vias 35 may be considered Through-Dielectric Vias (TDV) or the like, in some cases.

The interconnect structure 30 includes dielectric layers 32 (not individually illustrated) with conductive features 34 formed in the dielectric layers 32, in some embodiments. The conductive features 34 allow for electrical communication within the optical engine 100. The conductive features 34 may comprise conductive lines, conductive vias, conductive pads, metallization patterns, redistribution layers, or the like that provide electrical interconnections and electrical routing within the optical engine 100. Some conductive features 34 may be electrically connected to one or more photonic components 18 and/or to one or more vias 35, in some cases. In some cases, the interconnect structure 30 and the vias 35 may be formed as part of a Back End of Line (BEOL) process.

In some embodiments, the interconnect structure 30 is formed of alternating layers of dielectric material (e.g., dielectric layers 32) and conductive material (e.g., conductive features 34). The conductive features 34 may be formed using any suitable processes such as deposition, damascene, dual damascene, or the like. In particular embodiments, the interconnect structure 30 may have multiple layers of conductive features 34, but the precise number of layers of conductive features 34 may be dependent upon the design of the optical engine 100. The dielectric layers 32 may be, for example, insulating layers and/or passivating layers, and may comprise silicon oxide, silicon nitride, a polymer, a molding material, the like, or a combination thereof. The conductive features 34 may include, for example, a metal or a metal alloy such as copper, silver, gold, tungsten, cobalt, ruthenium, aluminum, alloys thereof, combinations thereof, or the like. Other materials or formation techniques are possible.

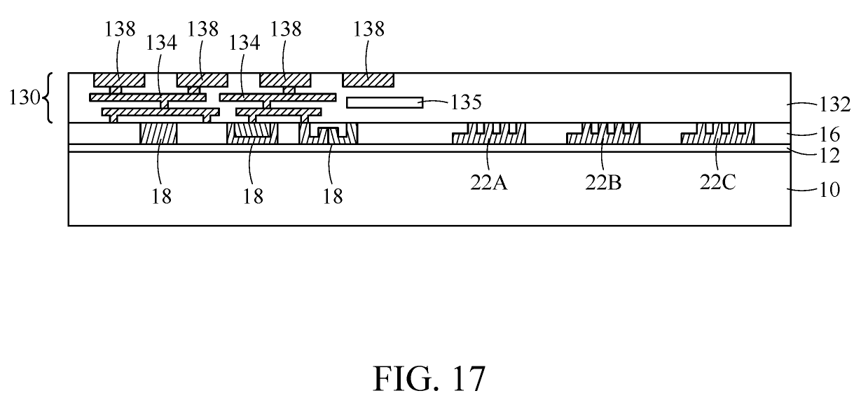

Additionally, during the manufacture of the interconnect structure 30, one or more photonic components (not illustrated) may be formed within the dielectric layers 32, in accordance with some embodiments. For example, in some embodiments, the photonic components in the interconnect structure 30 may include waveguides (e.g., silicon nitride waveguides or other types of waveguides), couplers, or the like. In some cases, one or more photonic components formed in the interconnect structure 30 may be optically coupled to each other and/or to one or more underlying photonic components 18. In this manner, the photonic components formed in the interconnect structure 30 may provide additional optical communication and optical interconnection within the optical engine 100. The photonic components may comprise waveguides similar to the waveguides 135 described below for the embodiment of FIG. 17.

In some embodiments, photonic components may be formed within the interconnect structure 30 by depositing a material for photonic components on a dielectric layer 32. The material for the photonic components may be a dielectric material such as silicon nitride, silicon oxide, silicon oxynitride, polymer, combinations of these, or the like, or a semiconductor material such as silicon, germanium, or the like. The material may then be patterned into suitable shapes for the photonic components using suitable photolithography and etching techniques. Another dielectric layer 32 may then be deposited over the photonic components. In particular embodiments, the interconnect structure 30 may have multiple layers of photonic components, but the precise number of layers of photonic components may be dependent upon the design of the optical engine 100. In some cases, the interconnect structure 30, the dielectric layer 16, and the photonic components 18 (including the grating couplers 22A-C) may collectively be considered a photonic die, a photonic integrated circuit (PIC), a photonic interconnect structure, or the like.

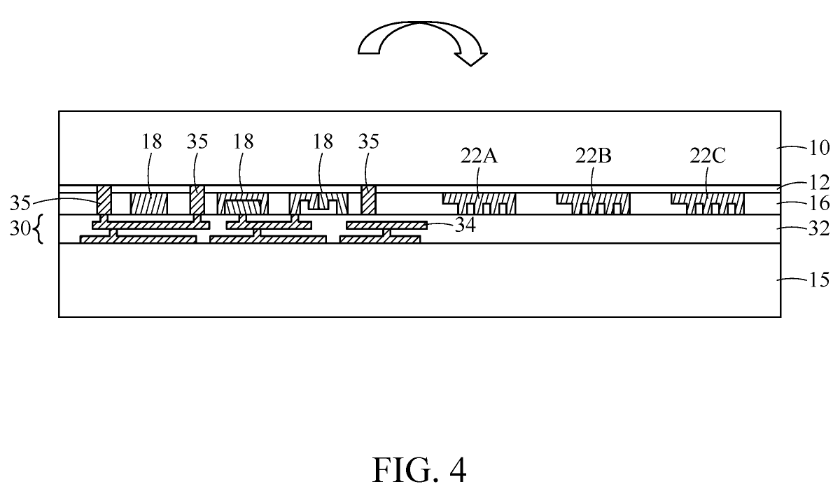

In FIG. 4, the structure is flipped over and attached to a carrier 15, in accordance with some embodiments. The carrier 15 may be, for example, a wafer (e.g., a silicon wafer), a panel, or a substrate such as silicon oxide, glass, ceramic, plastic, or any other suitable material. The structure may be attached to the carrier 15 by bonding, an adhesive, a Die Attach Film (DAF), or any other suitable technique. In some embodiments, the grating couplers 22A-C may be formed “upside-down” in FIG. 2 so that the grating couplers 22A-C are in an appropriate orientation when the structure is flipped over.

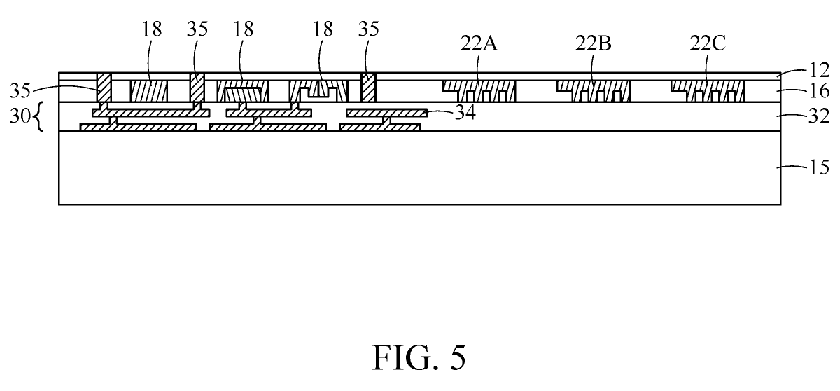

In FIG. 5, the substrate 10 is removed, in accordance with some embodiments. The substrate 10 may be removed using a planarization process (e.g., a CMP or grinding process), an etching process, the like, or a combination thereof. Removing the substrate 10 exposes the dielectric layer 12 and the vias 35, in some cases. After removing the substrate 10, surfaces of the dielectric layer 12 and the vias 35 may be level, in some cases. In other embodiments, removing the substrate 10 also thins or removes the dielectric layer 12.

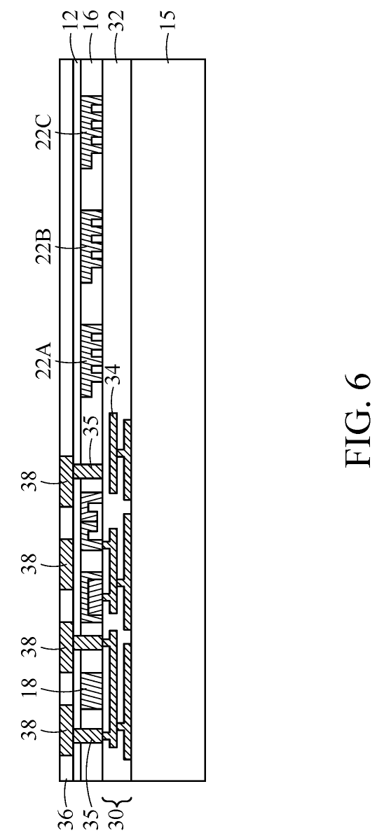

In FIG. 6, a bonding layer 36 and bonding pads 38 are formed over the dielectric layer 12, in accordance with some embodiments. In some cases, the bonding layer 36 and the bonding pads 38 may be considered a bonding structure or the like. In other embodiments, one or more layers of conductive features, such as an interconnect structure or the like, may be formed over the dielectric layer 12 before forming the bonding structure. In some embodiments, the bonding layer 36 is a material suitable for dielectric-to-dielectric bonding (e.g., direct bonding, fusion bonding, or the like), such as silicon oxide, silicon nitride, silicon oxynitride, or the like. In some embodiments, the material of the bonding layer 36 is different than the material of the dielectric layer 12. Other materials are possible.

The bonding pads 38 may be conductive pads (e.g., metal pads) or the like, and may include via portions (not separately illustrated) that physically and electrically contact underlying vias 35. In some embodiments, the bonding pads 38 may be formed by first forming openings (not separately illustrated) in the bonding layer 36 that expose some vias 35, depositing an optional liner in the openings, and then depositing a conductive material in the openings. The conductive material may be similar to those described for the conductive features 34 above. For example, the conductive material may be copper or a copper alloy, in some embodiments. A planarization process (e.g., a CMP process or a grinding process) may be performed to remove excess conductive material such that top surfaces of the bonding pads 38 and the bonding layer 36 are approximately level. This is an example, and the bonding pads 38 may be formed using other materials, techniques, or process steps.

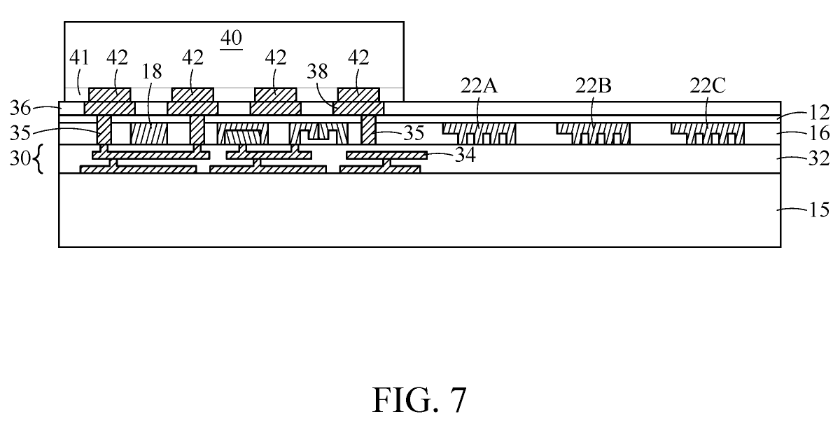

In FIG. 7, an electronic die 40 is bonded to the bonding layer 36 and the bonding pads 38, in accordance with some embodiments. The electronic die 40 may be, for example, a semiconductor device, die, chip, or package that may comprise integrated circuits and may interact with the photonic components 18 using electrical signals. For example, the electronic die 40 may include controllers, drivers, transimpedance amplifiers, transistors (e.g., Metal Oxide Semiconductor Field-Effect Transistors (MOSFETs), Fin Field-Effect Transistors (FinFETs), Gate-All-Around (GAA) transistors, nanostructure transistors (e.g., nano-FETs, nanosheet FETs, or the like), or the like), other active devices, resistors, capacitors, other passive devices, the like, or combinations thereof. In some embodiments, the electronic die 40 may include a substrate; a semiconductor structure over the substrate and comprising a channel region and a source/drain region disposed along a first direction; an isolation feature alongside the semiconductor structure; a source/drain feature over the source/drain region, wherein a bottom surface of the source/drain feature is lower than a top surface of the semiconductor structure, wherein, along a second direction different from the first direction, a width of the source/drain feature is greater than a width of the channel region such that a portion of the source/drain feature overhangs the isolation feature. In some embodiments, an interlayer dielectric (ILD) layer is disposed over the source/drain feature, wherein an interface between the source/drain feature and the ILD layer is non-linear. Accordingly, the electronic die 40 may be considered an electronic integrated circuit (EIC) structure or the like. In some embodiments, the integrated circuits may be configured to interface with the photonic components 18. For example, the electronic die 40 may process electrical signals received from photonic components 18, may control the operation of the photonic components 18, and/or may generate electrical signals that photonic components 18 convert into optical signals. One electronic die 40 is shown in FIG. 7, but an optical engine 100 may include two or more electronic dies 40 in other embodiments.

In some embodiments, the electronic die 40 may provide Serializer/Deserializer (SerDes) functionality. In this manner, the electronic die 40 may act as part of an I/O interface between optical signals and electrical signals within the optical engine 100 or within a package or package component comprising the optical engine 100. In some embodiments, an electronic die 40 may comprise one or more processing devices, such as a Central Processing Unit (CPU or “xPU”), a Graphics Processing Unit (GPU), an Application-Specific Integrated Circuit (ASIC), a High-Performance Computing (HPC) die, a logic die, the like, or a combination thereof. An electronic die 40 may include one or more memory devices, which may be a volatile memory such as Dynamic Random-Access Memory (DRAM), Static Random-Access Memory (SRAM), High-Bandwidth Memory (HBM), another type of memory, or the like. Other electronic dies 40 or configurations thereof are possible.

In some embodiments, the electronic die 40 may include bonding pads 42 formed in a bonding layer 41. The bonding pads 42 may be conductive pads (e.g., copper pads or the like) and may be similar to the bonding pads 38, in some cases. The bonding layer 41 of the electronic die 40 may be a dielectric material suitable for dielectric-to-dielectric bonding (e.g., silicon oxide or the like) and may be similar to the bonding layer 36, in some cases. The electronic die 40 is bonded to the bonding structure using dielectric-to-dielectric bonding and/or metal-to-metal bonding (e.g., direct bonding, fusion bonding, oxide-to-oxide bonding, hybrid bonding, or the like). In some embodiments, the bonding layer 41 of the electronic die 40 is bonded to the bonding layer 36 using a dielectric-to-dielectric bonding process, and bonding pads 42 of the electronic die 40 are bonded to corresponding bonding pads 38 using a metal-to-metal bonding process.

In some embodiments, the bonding process may be initiated by activating the bonding surfaces of the electronic die 40 and the bonding structure, which can facilitate bonding of the bonding surfaces. Activating the bonding surfaces may comprise, for example, a dry treatment, a wet treatment, a plasma treatment, exposure to an inert gas plasma, exposure to H₂, exposure to N₂, exposure to O₂, combinations thereof, or the like. For embodiments in which a wet treatment is used, an RCA cleaning process may be used, for example. In other embodiments, the activation process may comprise other types of treatments. After the activation process, the electronic die 40 is aligned and placed into physical contact with the interconnect structure 30. A thermal treatment and/or contact pressure may be applied, in some cases. In some embodiments, the resulting bonded structure is subsequently baked, annealed, pressed, or otherwise treated to strengthen or finalize the bond. This is an example, and other bonding processes are possible. In other embodiments, the electronic die 40 may comprise conductive connectors (e.g. solder bumps, copper bumps, or the like), and may be bonded to the bonding pads 38 using these conductive connectors.

A width of a bonding pad 42 may be similar to or different from a width of the corresponding bonding pad 38. A bonding pad 42 may have a sidewall that is approximately aligned to (e.g., flush with) or offset from a sidewall of the corresponding bonding pad 38. In some cases, a bonding pad 38 may directly contact the bonding layer 41 of the electronic die 40. Other configurations or arrangements are possible.

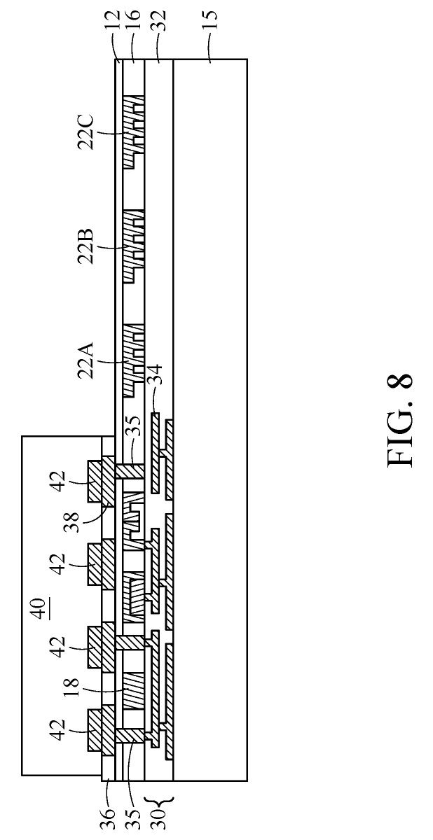

In FIG. 8, portions of the bonding layer 36 are removed, in accordance with some embodiments. For example, portions of the bonding layer 36 over the grating couplers 22A-C may be removed, in some embodiments. Removing the bonding layer 36 over the grating couplers 22A-C may allow for improved optical communication to the grating couplers 22A-C from an overlying photonic component (e.g., an optical fiber or the like). In some embodiments, the electronic die 40 acts as a mask such that portions of the bonding layer 36 not covered by the electronic die 40 are removed using a suitable etching process. In some embodiments, the portions of the bonding layer 36 are removed using suitable photolithography and etching techniques. In some cases, the bonding layer 36 may be etched using a selective etching process that etches the material of the bonding layer 36 faster than the material of the dielectric layer 12. Other techniques or etching processes are possible. In other embodiments, portions of the bonding layer 36 are not removed.

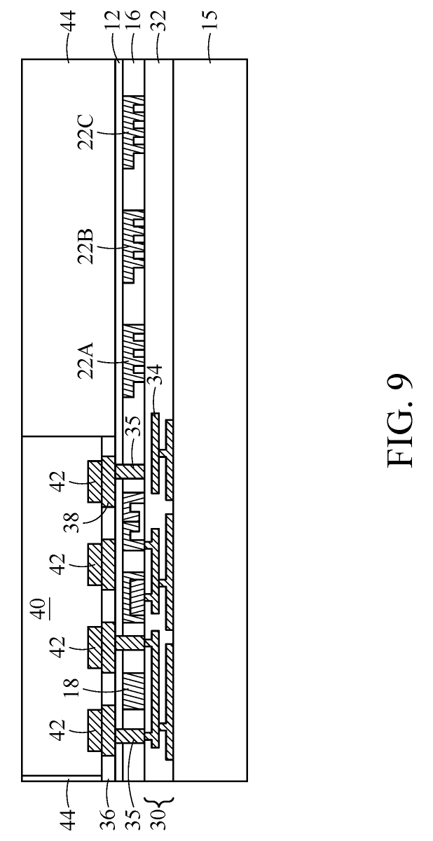

In FIG. 9, a dielectric material 44 is formed over the electronic die 40 and the dielectric layer 12, in accordance with some embodiments. The dielectric material 44 may be formed of silicon oxide, silicon nitride, a polymer, the like, or a combination thereof. The dielectric material 44 may be formed by CVD, PVD, ALD, a spin-on process, the like, or a combination thereof. In some embodiments, the dielectric material 44 may be formed by HDP-CVD, FCVD, PECVD, the like, or a combination thereof. The dielectric material 44 may be a gap-fill material in some embodiments, which may include one or more of the example materials above. In some embodiments, the dielectric material 44 may be a material (e.g., silicon oxide) that is substantially transparent to light at wavelengths suitable for transmitting optical signals or optical power. For example, the dielectric material 44 may allow optical signals or optical power to be transmitted between a grating coupler 22 and an overlying optical fiber or the like. The dielectric material 44 may be a material similar to that of the dielectric layers 32 and/or the dielectric layer 16, in some embodiments. Other dielectric materials formed by any acceptable processes may be used. The dielectric material 44 may be planarized using a planarization process (e.g., a CMP or grinding process). In some embodiments, the planarization process may expose the electronic die 40 such that surfaces of the electronic die 40 and the dielectric material 44 are coplanar. In other embodiments, the electronic die 40 is covered by the dielectric material 44.

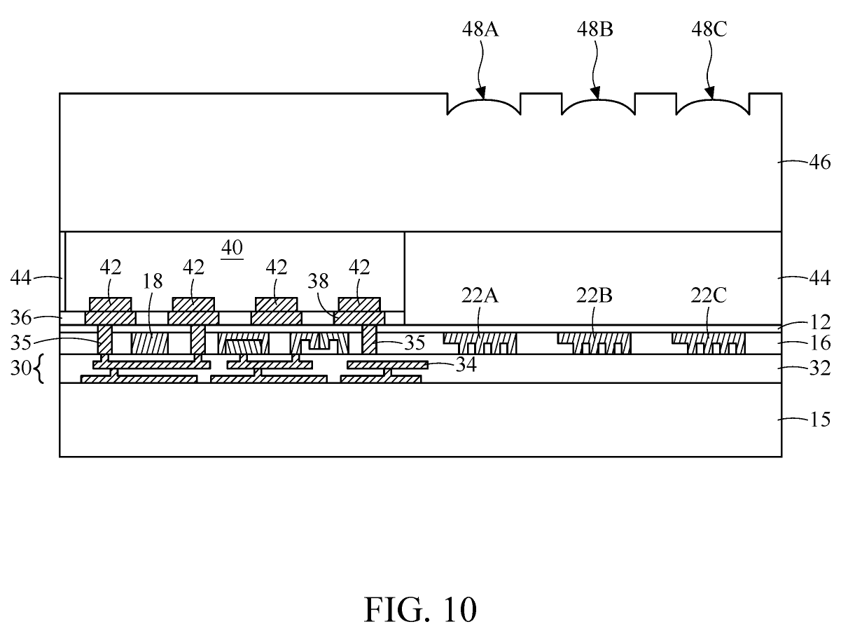

In FIG. 10, a support 46 is attached to the structure, in accordance with some embodiments. The support 46 is a rigid structure that is attached to the structure in order to provide structural or mechanical stability. The use of a support 46 can reduce warping or bending, which can improve the performance of the photonic components 18 within the optical engine 100. The support 46 may be attached to the structure (e.g., to the dielectric material 44 and/or to the electronic die 40) using dielectric-to-dielectric bonding, an adhesive layer, or the like. For example, in some embodiments, a bonding layer is deposited on the structure, and then the support 46 is bonded to the bonding layer using dielectric-to-dielectric bonding. In other embodiments, the support 46 is attached at a different step in the manufacture of the optical engine 100, such as after formation of the redistribution structure 50, described below.

In some embodiments, the support 46 is formed of materials transparent to relevant wavelengths of light such that optical signals may be transmitted through the support 46. For example, in some embodiments, the support 46 is formed of silicon, though other materials are possible. In some embodiments, the support 46 may comprise a carrier or a wafer, such as a silicon wafer or the like. The support 46 may be diced or trimmed during a subsequent singulation process, described below. Other types or materials of a support 46 are possible.

In some embodiments, one or more lenses 48 are formed in the upper surface of the support 46. FIG. 10 illustrates three lenses 48A-C, but another number or arrangement of lenses 48 are possible. In some embodiments, a lens 48 facilitates optical coupling between a grating coupler 22 and an overlying optical fiber coupler or the like. For example, the lenses 48A, 48B, and 48C may be configured to transmit optical signals to or receive optical signals from respectively corresponding grating couplers 22A, 22B, and 22C. In some cases, one lens 48 is associated with multiple grating couplers 22, or one grating coupler 22 is associated with multiple lenses 48. In some cases, the lenses 48 may be considered “microlenses” or the like.

In some embodiments, the lenses 48 are formed in the support 46 using one or more patterning steps, which may include suitable photolithography and etching processes. In this manner, the lenses 48 may comprise recesses or the like in a top surface of the support 46. In other embodiments, the lenses 48 are formed separately and are attached to the support 46. As shown in FIG. 10, each lens 48 may be located approximately over its corresponding grating coupler 22 and may overlap its corresponding grating coupler 22 in some cases. In some embodiments, an index-matching material, an anti-reflective coating (ARC), an optical glue, or the like (not shown) is deposited over the lenses 48. The lenses 48 shown in FIG. 10 are examples, and lenses 48 may have other numbers, arrangements, shapes, or sizes than shown.

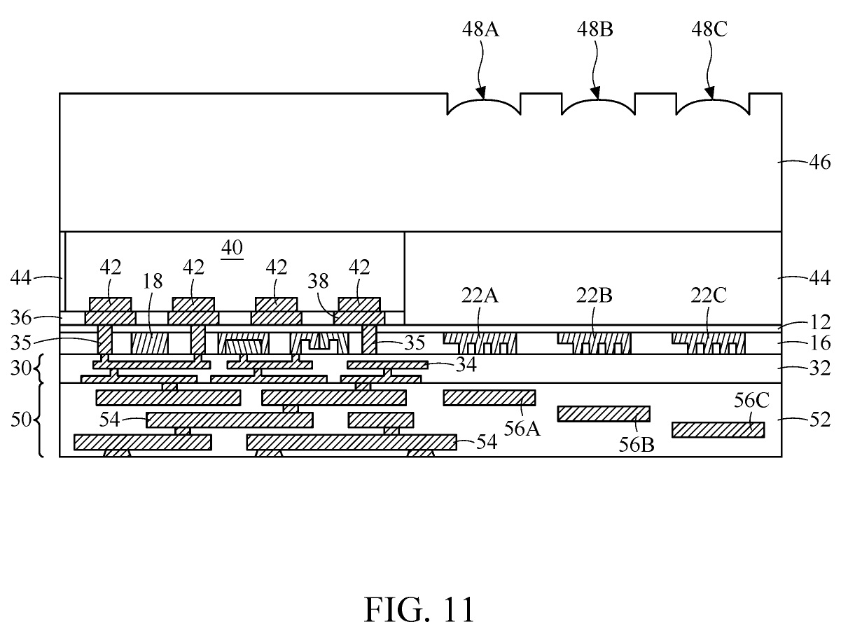

In FIG. 11, the carrier 15 is removed and a redistribution structure 50 is formed on the interconnect structure 30, in accordance with some embodiments. The redistribution structure 50 includes conductive features 54 and reflectors 56 formed in one or more dielectric layers 52 (not individually illustrated). The conductive features 54 may comprise, for example, conductive lines, conductive vias, conductive pads, metallization patterns, redistribution layers, or the like. The conductive features 54 may provide electrical interconnections within the optical engine 100, and may be physically and/or electrically connected to the conductive features 34 of the interconnect structure 30. The reflectors 56 are formed underneath corresponding grating couplers 22 and facilitate transmission of optical signals to or from the grating couplers 22. For example, FIG. 11 illustrates three reflectors 56A, 56B, and 56C that are respectively associated with grating couplers 22A, 22B, and 22C. The reflectors 56 may be formed at different distances from their corresponding grating couplers 22, as shown in FIG. 11. In some embodiments, the reflectors 56 are formed using the same process steps as the conductive features 54, described below. Accordingly, the reflectors 56 may be formed of metal and may be considered part of the metallization patterns, redistribution layers, or the like of the redistribution structure 50, in some cases. In some cases, one or more reflectors 56 may be electrically connected to conductive features 54 and may also provide electrical interconnections within the optical engine 100. In other cases, the reflectors 56 are electrically isolated from the conductive features 54. The illustrated redistribution structure 50 is an example, and a redistribution structure 50 may have a different number or arrangement of conductive features 54 or reflectors 56 than shown.

The dielectric layers 52 of the redistribution structure 50 may be formed of one or more suitable dielectric materials, such as silicon oxide, silicon nitride, silicon oxynitride, spin-on glass, PBO, polyimide, a BCB-based polymer, other polymers or photosensitive polymers, or the like. The dielectric layers 52 may be formed by spin coating, lamination, CVD, PVD, ALD, the like, or a combination thereof. After each dielectric layer 52 is formed, it may be patterned to form openings that expose portions of underlying conductive features (e.g., conductive features 34 or conductive features 54). The patterning may be performed using an acceptable process, such as by exposing the dielectric layer 52 to light and then developing the dielectric layer 52, when the dielectric layer 52 is a photosensitive material. The dielectric layer 52 may be patterned using other suitable photolithography and etching techniques.

In some embodiments, layers of conductive features 54 and/or reflectors 56 may be formed on corresponding dielectric layers 52. Conductive features 54 and reflectors 56 may extend on a surface of a dielectric layer 52, and conductive features 54 may also extend through the dielectric layer 52. As an example to form a layer of conductive features 54 and a reflector 56, a seed layer (not separately illustrated) may be formed on a dielectric layer 52 and in the openings through the dielectric layer 52. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as PVD or the like. A photoresist is then formed and patterned on the seed layer. The photoresist may be formed by spin coating or the like and may be exposed to light for patterning. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may include a metal or a metal alloy, such as copper, titanium, tungsten, aluminum, an alloy comprising copper at an atomic percentage of greater than 80%, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the conductive features 54 and/or reflectors 56.

The process for forming the redistribution structure 50 described above is an example, and other techniques or materials may be used to form the redistribution structure 50. For example, the conductive features 54 and/or the reflectors 56 may be formed using any suitable processes such as deposition, damascene, dual damascene, or the like. In other embodiments, the reflectors 56 may be formed using different materials than the conductive features 54 or using separate process steps. In some embodiments, a size (e.g., linewidth, thickness, pitch, etc.) of the conductive features 54 may be greater than a size of the conductive features 34. In some embodiments, a size of the reflectors 56 may be different than a size of the conductive features 54. In other embodiments, waveguides (e.g., silicon nitride waveguides or other types of waveguides) may be formed in the redistribution structure 50 to provide optical communication within the optical engine 100.

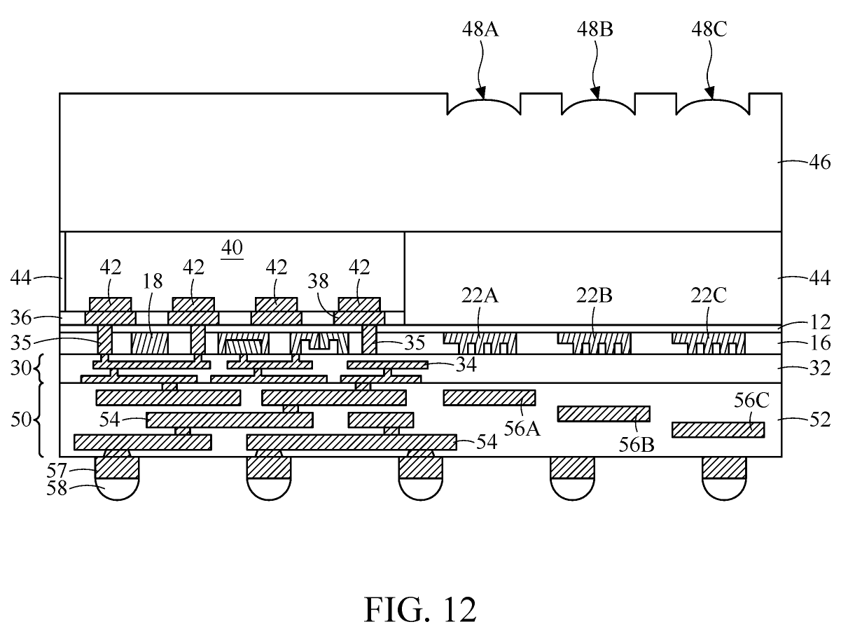

In FIG. 12, conductive connectors 58 are formed on the redistribution structure 50, in accordance with some embodiments. The conductive connectors 58 may be used to electrically connect the optical engine 100 to an external structure such as a package substrate, an organic core substrate, an interposer, or the like. In some embodiments, an optional passivation layer (not illustrated) is formed over the redistribution structure 50. In some cases, the passivation layer may be a dielectric layer 52 or otherwise may be considered part of the redistribution structure 50. Under-bump metallizations (UBMs) 57 may be formed over the redistribution structure 50 to make physical and electrical contact to conductive features 54. The UBMs 57 may be formed of one or more conductive materials using a suitable process, such as plating. In some embodiments, the UBMs 57 are not formed.

The conductive connectors 58 are then formed on the UBMs 57, in accordance with some embodiments. The conductive connectors 58 may be, for example, ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 58 may include a conductive material such as solder, copper, aluminum, gold, nickel, silver, palladium, tin, the like, or a combination thereof. In some embodiments, the conductive connectors 58 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 58 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In other embodiments, the conductive connectors 58 are omitted and the UBMs 57 are bonding pads used for metal-to-metal bonding to an external component.

In FIG. 13, the structure is singulated to form individual optical engines 100, in accordance with some embodiments. In some embodiments, the singulation process comprises cutting along scribe regions (not illustrated) to singulate the structure into individual optical engines 100. The singulation process may include sawing, dicing, a laser cutting process, an etching process, or the like. In some cases, after singulation, one or more sidewalls of an electronic die 40 may be exposed. In other cases, sidewalls of one or more electronic dies 40 may remain covered by the dielectric material 44. In other embodiments, the singulation process may be performed at an earlier stage of the process of forming an optical engine 100.

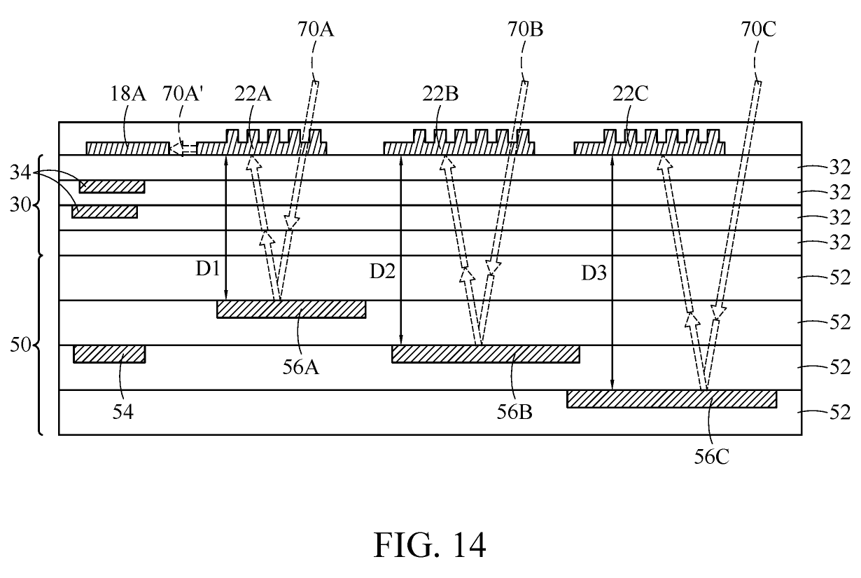

FIG. 14 illustrates a magnified portion of an optical engine 100 including grating couplers 22A-C and reflectors 56A-C, in accordance with some embodiments. FIG. 14 may illustrate a portion of an optical engine 100 similar to the optical engine 100 described for FIG. 13. For example, FIG. 14 illustrates a portion of an interconnect structure 30 and a portion of a redistribution structure 50. As shown in FIG. 14, in some embodiments, each reflector 56A-C may be formed over a different dielectric layer 52. In some embodiments, reflectors 56A-C may be separated by one or more dielectric layers 52. Other configurations, arrangements, or numbers of features are possible.

FIG. 14 also illustrates optical signals 70A-C (e.g., light) being transmitted from above, such as from one or more overlying lenses 48, that is coupled into the grating couplers 22A-C. For example, optical signal 70A is transmitted from above toward reflector 56A. The optical signal 70A is reflected by reflector 56A toward grating coupler 22A, where the optical signal 70A is coupled into the grating coupler 22A. The optical signal 70 may then be coupled into a photonic component 18, such as waveguide 18A illustrated in FIG. 14. The optical signal 70A’ represents the optical signal 70A being coupled into the waveguide 18A from the grating coupler 22A. Similarly, the optical signal 70B is reflected by reflector 56B into the grating coupler 22B, and the optical signal 70C is reflected by reflector 56C into the grating coupler 22C. A portion of an optical signal 70 may or may not pass through its corresponding grating coupler 22 before being reflected by its corresponding reflector 56. As shown in FIG. 14 and described previously, the reflectors 56A, 56B, and 56C are each a different respective distance D1, D2, and D3 from their respectively associated grating couplers 22A, 22B, and 22C. For example, the distance D1 is smaller than the distance D2, and the distance D2 is smaller than the distance D3. Other distances or combinations of distances are possible. For example, in some embodiments, two or more of the distances D1, D1, and D3 may be the same distance.

In some embodiments, each grating coupler 22A-C may be configured for a particular wavelength or a particular range of wavelengths. The periodicity of a grating coupler 22 may refer, for example, to a spacing or pitch between regions of similar refractive index, between similar physical structures, or the like that form the periodic optical structure of the grating coupler 22. In some cases, each grating coupler 22A-C may have a different periodicity that corresponds to or is optimized for coupling optical signals of a particular wavelength or particular range of wavelengths. As an example, the grating coupler 22A may be configured for smaller wavelength(s) than the grating coupler 22B, and the grating coupler 22B may be configured for smaller wavelength(s) than the grating coupler 22C. In such cases, the period of the grating coupler 22A may be smaller than the period of the grating coupler 22B, which may be smaller than the period of the grating coupler 22C. Other configurations, periodicities, or designs for grating couplers 22A-C with different corresponding wavelengths are possible.

It should be noted that the speed of light C within a medium is given by the equation C=f·λ, wherein f is the frequency of light and λ is the wavelength of light. Thus, optical signals 70A-C having a longer wavelength λ have a correspondingly faster speed C. In some embodiments, the distances D1, D2, and D3 between the grating couplers 22A-C and the reflectors 56A-C may be configured to compensate for the different speeds of optical signals 70A-C having different wavelengths. For example, the distance between a reflector 56 and a grating coupler 22 may be larger for optical signals 70 that have a longer wavelength (e.g., distance D3 in FIG. 14) to provide a longer optical path, and the distance between a reflector 56 and a grating coupler 22 may be shorter for optical signals 70 that have a shorter wavelength (e.g., distance D1) to provide a shorter optical path. In some embodiments, the distances D1-D3 may be chosen such that optical signals 70A-C of different wavelengths arrive at their corresponding grating couplers 22A-C at approximately the same time. In other words, the positions of the reflectors 56A-C may be at different heights within the redistribution structure 50 such that optical signals 70A-C that are simultaneously transmitted to the optical engine 100 arrive at their corresponding grating couplers 22A-C simultaneously or nearly simultaneously. This can improve coupling and optical signal processing of optical signals having different wavelengths. In this manner, the distances D1-D3 may be based on the wavelength(s) of the optical signals 70A-C associated with that distance D1-D3. For example, each distance D1-D3 may be proportional to the wavelength of the corresponding optical signal 70A-C, in some cases. In some embodiments, the distances D1-D3 can be configured to control other optical characteristics, such as optical signal phase, optical signal timing, optical path location, etc. In this manner, having reflectors 56A-C at different distances D1-D3 from the grating couplers 22A-C can allow for optical paths of the optical signals 70A-C to be optimized for different wavelengths, which can improve optical coupling efficiency and reduce optical loss.

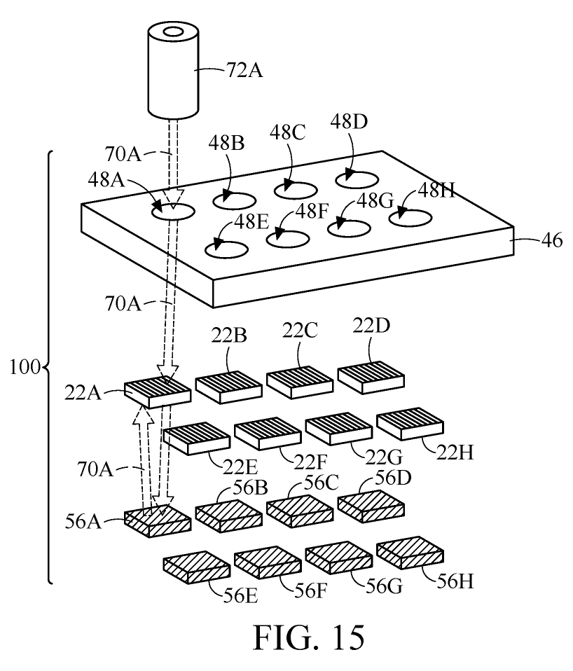

FIG. 15 illustrates a schematic of an optical engine 100 in a perspective view. The optical engine 100 may be similar to the optical engine 100 described previously. For clarity, the illustrated feature of the optical engine 100 are the grating couplers 22A-H, reflectors 56A-H, and a support 46 including lenses 48A-H. The grating couplers 22A-H, reflectors 56A-H, and the lenses 48A-H may be similar to those described previously for FIGS. 13-14. For example, some grating couplers 22A-H may be different vertical distances from their corresponding reflectors 56A-H. Each lens 48A-H is optically coupled to a respectively corresponding reflector 56A-H, and each reflector 56A-H is optically coupled to a respectively corresponding grating coupler 22A-H. In some embodiments, the lenses 48A-H may be arranged in an array. The number or arrangement of grating couplers 22A-H, reflectors 56A-H, and/or lenses 48A-H may be different in other embodiments. FIG. 15 also illustrates a representative optical fiber 72A overlying the optical engine 100. In some cases, the optical fiber 72A may be a part of a fiber array, fiber array unit (FAU), or the like. The optical fiber 72A is configured such that optical signals 70A may be transmitted from the optical fiber 72A to the lens 48A, which directs the optical signals 70A to the reflector 56A, which reflects the optical signals 70A into the grating coupler 22A. Other optical fibers (not illustrated) may be coupled to the other lenses 48B-H to transmit corresponding optical signals (not illustrated) that are coupled into corresponding grating couplers 22B-H. In some cases, more than one optical signal may be provided from the same optical fiber. For clarity, some features of the optical engine 100 and other components are not illustrated.

In some embodiments, the optical signals 70 transmitted into each grating coupler 22A-H have a different wavelength (or a different range of wavelengths). Each grating coupler 22A-H may be configured to receive optical signals 70 of a particular wavelength or range of wavelengths. The locations of a reflector 56 56A-H may be determined based on a wavelength of the optical signals 70 received by that reflector 56, as described previously. As an example of Course Wavelength Division Multiplexing (CWDM), the grating couplers 22A-H may be configured to receive corresponding optical signals that have wavelengths separated by about 0.1 nm to about 40 nm. In some embodiments, the wavelengths may be separated by about 10 nm to about 25 nm. In other words, in a CWDM configuration, each grating coupler 22A-H may be configured to receive optical signals 70 within a range of wavelengths having a bandwidth of about 0.1 nm to about 40 nm. The bandwidth of each grating coupler 22A-H may be non-overlapping (e.g., may be separated), in some cases. In some embodiments, fewer grating couplers 22 (with corresponding reflectors 56 and lenses 48) may be used when the grating couplers 22 are configured to receive optical signals 70 over a larger bandwidth. The number of grating couplers 22, reflectors 56, and lenses 48 may depend on the number of separate optical signals 70 of different wavelengths or may depend on the bandwidths of the grating couplers 22. In this manner, the optical engines 100 described herein may be utilized to receive optical signals having multiple wavelengths with improved efficiency.

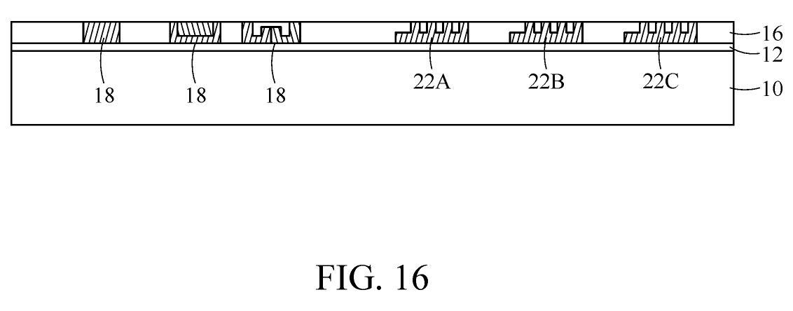

FIGS. 16-20 illustrate intermediate steps in the formation of an optical engine 200, in accordance with some embodiments. The optical engine 200 may be similar in some aspects to the optical engine 100. For example, the optical engine 200 includes grating couplers 22A-C and reflectors 56A-C that are separated by different distances, with the different distances based on the different wavelengths of optical signals. Some of the materials, process steps, or details may be similar to those described previously for FIGS. 1-13 and thus may not be repeated below.

FIG. 16 illustrates the formation of photonic components 18 and grating couplers 22A-C over a substrate 10, in accordance with some embodiments. The structure of FIG. 16 may be similar to the structure of FIG. 2, and may be formed using similar materials or techniques. For example, a substrate 10 having an overlying dielectric layer 12 and an overlying photonic layer (not illustrated in FIG. 16) may be received. The photonic layer may be patterned and otherwise processed to form photonic components 18 and grating couplers 22A-C, which may be similar to those described previously for FIG. 2. A dielectric layer 16 may be formed over the photonic components 18 and grating couplers 22A-C. Each grating coupler 22A-C may be configured for a particular wavelength or range of wavelengths.

In FIG. 17, an interconnect structure 130 is formed, in accordance with some embodiments. The interconnect structure 130 may include conductive features 134 formed in dielectric layers 132 (not individually illustrated). The conductive features 134 may include conductive lines and conductive vias and may be formed using materials or techniques similar to those described previously for the conductive features 34. The interconnect structure 130 may include bonding pads 138 at a top surface, which may be similar to the bonding pads 38 described previously.

Additionally, in some embodiments, the interconnect structure 130 may include one or more layers of waveguides 135. The waveguides 135 may be optically coupled to each other, to photonic components 18, and/or to grating couplers 22A-B. In some embodiments, a layer of waveguides 135 may be formed by depositing a waveguide material on a dielectric layer 132 and then patterning the waveguide material. The waveguide material may be a dielectric material such as silicon nitride, silicon oxide, silicon oxynitride, polymer, combinations of these, or the like. In other embodiments, the waveguide material may be a semiconductor material such as silicon, germanium, or the like. The waveguide material may be deposited using a suitable technique, such as ALD, PVD, or the like. The waveguide material may then be patterned using suitable photolithography and etching techniques to form a layer of waveguides 135. A dielectric layer 132 may then be deposited over the layer of the waveguides 135. The steps of depositing a waveguide material, patterning the waveguide material to form a layer of waveguides 135, and then depositing a dielectric layer 132 over the layer of waveguides 135 may be repeated to form multiple layers of waveguides 135. The precise number or arrangement of layers of waveguides 135 may be dependent upon the design of the optical engine 200.

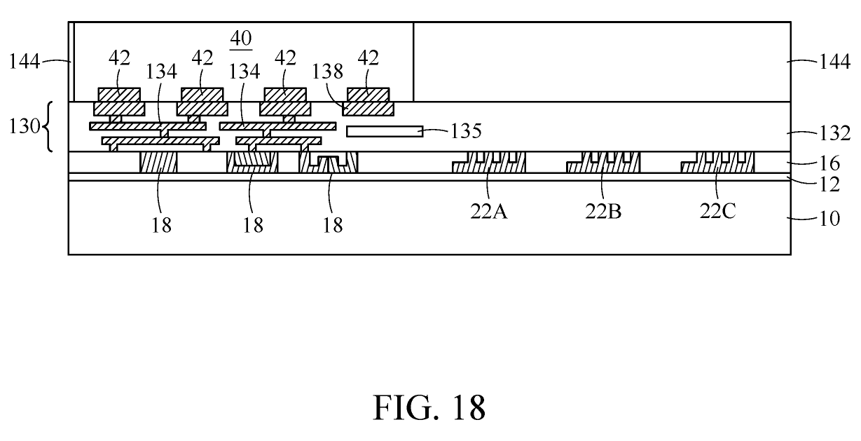

In FIG. 18, an electronic die 40 is bonded to the interconnect structure 130, in accordance with some embodiments. The electronic die 40 may be similar to the electronic die 40 described previously. The electronic die 40 may be bonded to the interconnect structure 130 using techniques described previously, such as using dielectric-to-dielectric bonding, metal-to-metal bonding, or the like. For example, bonding pads 42 of the electronic die 40 may be bonded to bonding pads 138 of the interconnect structure 130 using metal-to-metal bonding. After bonding the electronic die 40, a dielectric material 144 is deposited over the interconnect structure 130 and surrounding the electronic die 40. The dielectric material 144 may be similar to the dielectric material 44 described previously. After forming the dielectric material 144, a planarization process (e.g., a CMP or grinding process) may be performed. In some cases, after the planarization process, top surfaces of the electronic die 40 and the dielectric material 144 may be level.

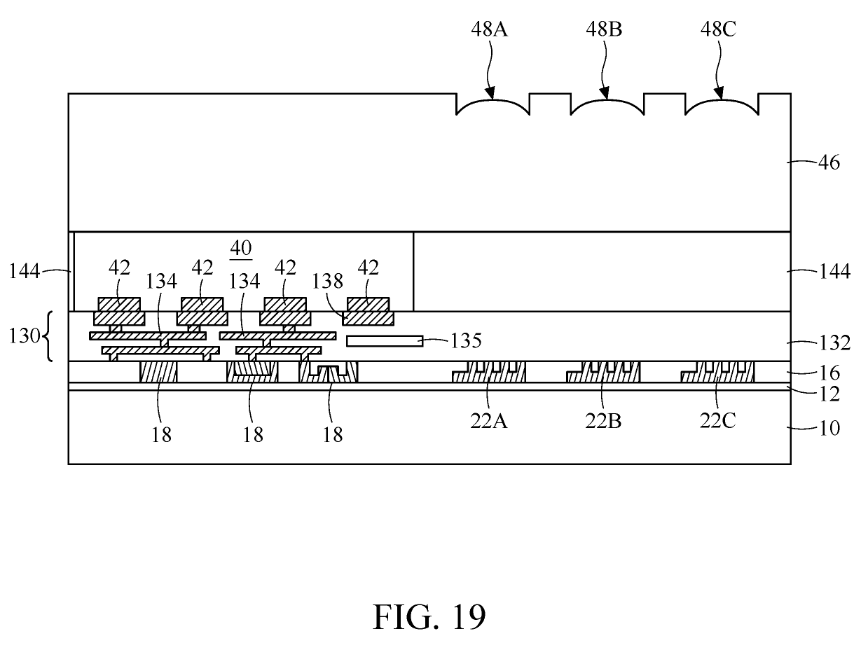

In FIG. 19, a support 46 is attached to the structure, in accordance with some embodiments. The support 46 may be similar to the support 46 described previously. For example, the support 46 may comprise multiple lenses 48A-C at a top surface, in which each lens 48A-C corresponds to a grating coupler 22A-C. The support 46 may be attached using dielectric-to-dielectric bonding, an adhesive, or another suitable technique.

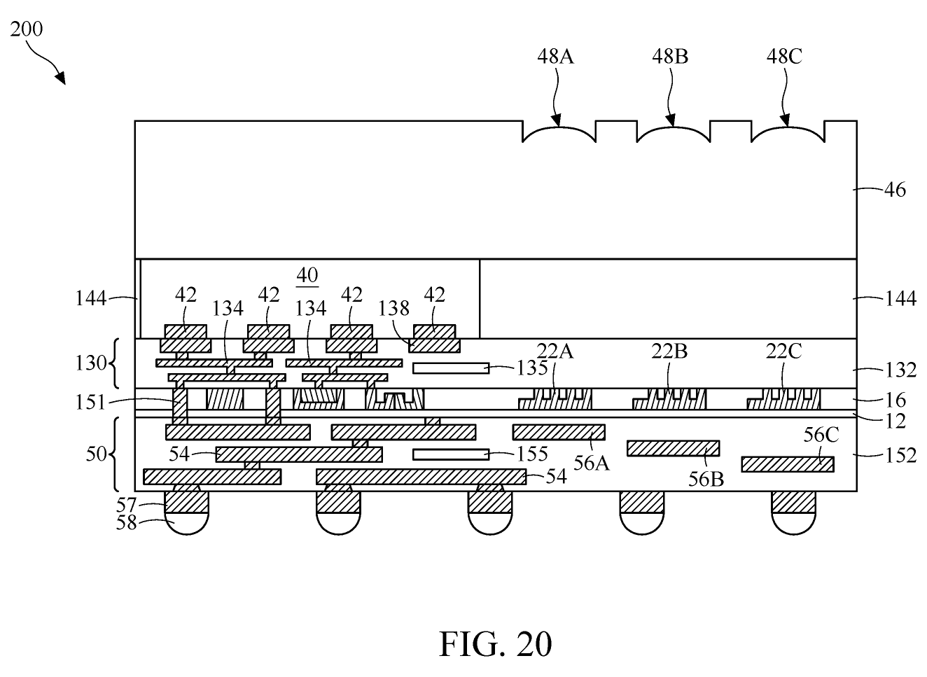

In FIG. 20, the substrate 10 is removed and a redistribution structure 150 is formed, in accordance with some embodiments. The substrate 10 may be removed using a planarization process (e.g., a CMP or grinding process) and/or an etching process. In some embodiments, vias 151 are formed extending through the dielectric layer 12 and the dielectric layer 16 to electrically contact the interconnect structure 130. The redistribution structure 150 may be similar to the redistribution structure 50 described previously. For example, the redistribution structure 150 may include conductive features 54 and reflectors 56A-C in dielectric layers 152 (not individually illustrated). The conductive features 54 may include, for example, conductive lines and conductive vias. Conductive features 54 may be electrically connected to the interconnect structure 130 by the vias 151, in some cases. The reflectors 56A-C may be similar to the reflectors 56A-C described previously. For example, each reflector 56A-C may be a metal feature underneath an associated grating coupler 22A-C, with a distance of the reflector 56A-C from its grating coupler 22A-C being larger for longer wavelength optical signals and smaller for smaller wavelength optical signals. The redistribution structure 150 may also include waveguides 155, which may be formed using similar materials or techniques as the waveguides 135. The waveguides 155 may be optically coupled to each other, to the photonic components 18, and/or to the grating couplers 22A-C. UBMs 57 and conductive connectors 58 may be formed on the redistribution structure 150. The UBMs 57 and conductive connectors 58 may be similar to those described previously.

Embodiments of the present disclosure have some advantageous features. An optical engine comprising multiple grating couplers configured for optical signals of different wavelengths can allow for more efficient multiplexing and processing of optical signals. By locating reflectors at different distances underneath the grating couplers, the reflectors can compensate for the different speeds of the optical signals due to their different wavelengths. For example, the optical paths of the different optical signals can be minimized by having different reflector distances, which can allow more simultaneous arrival of the optical signals at the grating couplers. This can improve optical coupling efficiency and reduce optical loss, improving the operation of the optical engine. The number or arrangement of grating couplers and reflectors may be configured for the particular characteristics of the optical signals and their wavelengths. In some cases, an array of lenses may be formed in a top surface of the optical engine, with each lens providing more efficient optical coupling from an overlying component, such as an optical fiber or the like. In this manner, the techniques described herein can facilitate efficient wavelength division multiplexing and can improve optical communication between photonic components or photonic packages. The use of grating couplers and reflectors as described herein can allow for increased design flexibility, smaller package size, improved bandwidth, and improved device performance. By forming reflectors in the redistribution structure of an optical engine, design flexibility can be improved and manufacturing cost can be reduced.

In an embodiment of the present disclosure, a method includes forming a first grating coupler and a second grating coupler in a first dielectric layer, wherein the first grating coupler is configured to couple optical signals of a first wavelength and the second grating coupler is configured to couple optical signals of a second wavelength; forming a bonding structure over a first side of the first dielectric layer; bonding an electronic die to the bonding structure; and forming a redistribution structure over a second side of the first dielectric layer, wherein the redistribution structure includes first conductive features; a first reflector overlapping the first grating coupler; and a second reflector overlapping the second grating coupler. In an embodiment, forming the redistribution structure includes forming the second reflector after forming the first reflector. In an embodiment, the first reflector is a first distance from the first grating coupler and the second reflector is a second distance from the second grating coupler, wherein the first distance is different than the second distance. In an embodiment, the method includes forming a support over the electronic die, wherein the support includes a first lens associated with the first grating coupler and a second lens associated with the second grating coupler. In an embodiment, the first distance is longer than the second distance, and the first wavelength is longer than the second wavelength. In an embodiment, the method includes forming a waveguide in the first dielectric layer, wherein the first grating coupler is optically coupled to the waveguide. In an embodiment, the first reflector and at least one first conductive feature are formed simultaneously. In an embodiment, the first wavelength is at least 10nm different from the second wavelength.

In an embodiment of the present disclosure, a method includes patterning a material to form photonic components that include a waveguide and multiple grating couplers; and forming a redistribution structure over the photonic components, wherein forming the redistribution structure includes forming conductive features and reflectors in dielectric layers, wherein forming the reflectors includes: forming a first dielectric layer; forming a first reflector on the first dielectric layer; forming a second dielectric layer over the first reflector; and forming a second reflector on the second dielectric layer. In an embodiment, each grating has a different periodicity. In an embodiment, at least one reflector is electrically connected to at least one conductive feature. In an embodiment, each reflector overlaps a respective grating coupler. In an embodiment, each reflector is a different vertical distance from the respectively overlapping grating coupler. In an embodiment, the method includes attaching a support over the photonic components, wherein the support includes an array of microlenses. In an embodiment, forming the conductive features includes forming a first conductive feature on the first dielectric layer. In an embodiment, the waveguide is continuous with a first grating coupler.

In an embodiment of the present disclosure, a device includes: a redistribution structure that includes metal lines, a first metal reflector, and a second metal reflector; photonic components over the redistribution structure, wherein the photonic components include: a waveguide; a first grating coupler, wherein the first grating coupler is optically coupled to the first metal reflector, wherein the first grating coupler is a first distance from the first metal reflector; and a second grating coupler, wherein the second grating coupler is optically coupled to the second metal reflector, wherein the second grating coupler is a second distance from the second metal reflector that is different than the first distance; and an electronic die over the photonic components, wherein the electronic die is electrically connected to the redistribution structure. In an embodiment, the device includes a support over the electronic die, wherein the support includes a first lens that is optically coupled to the first metal reflector and a second lens that is optically coupled to the second metal reflector. In an embodiment, the device includes an interconnect structure between the redistribution structure and the photonic components, wherein the interconnect structure has a pitch that is smaller than that of the redistribution structure. In an embodiment, the first grating coupler is configured to couple light having a first range of wavelengths and the second grating coupler is configured to couple light having a second range of wavelengths, wherein the first range and the second range are different.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first grating coupler and a second grating coupler in a first dielectric layer, wherein the first grating coupler is configured to couple optical signals of a first wavelength and the second grating coupler is configured to couple optical signals of a second wavelength;
forming a bonding structure over a first side of the first dielectric layer;
bonding an electronic die to the bonding structure; and
forming a redistribution structure over a second side of the first dielectric layer, wherein the redistribution structure comprises:
a plurality of first conductive features;
a first reflector overlapping the first grating coupler; and
a second reflector overlapping the second grating coupler.

2. The method of claim 1, wherein forming the redistribution structure comprises forming the second reflector after forming the first reflector.

3. The method of claim 1, wherein the first reflector is a first distance from the first grating coupler, wherein the second reflector is a second distance from the second grating coupler, wherein the first distance is different than the second distance.

4. The method of claim 1, further comprising forming a support over the electronic die, wherein the support comprises a first lens associated with the first grating coupler and a second lens associated with the second grating coupler.

5. The method of claim 1, wherein the first distance is longer than the second distance, and wherein the first wavelength is longer than the second wavelength.

6. The method of claim 1, further comprising forming a waveguide in the first dielectric layer, wherein the first grating coupler is optically coupled to the waveguide.

7. The method of claim 1, wherein the first reflector and at least one first conductive feature are formed simultaneously.

8. The method of claim 1, wherein the first wavelength is at least 10nm different from the second wavelength.

9. A method comprising:
patterning a material to form a plurality of photonic components comprising a waveguide and a plurality of grating couplers; and
forming a redistribution structure over the plurality of photonic components, wherein forming the redistribution structure comprises forming a plurality of conductive features and a plurality of reflectors in a plurality of dielectric layers, wherein forming the plurality of reflectors comprises:
forming a first dielectric layer of the plurality of dielectric layers;
forming a first reflector of the plurality of reflectors on the first dielectric layer;
forming a second dielectric layer of the plurality of dielectric layers over the first reflector; and
forming a second reflector of the plurality of reflectors on the second dielectric layer.

10. The method of claim 9, wherein each grating coupler of the plurality of grating couplers has a different periodicity.

11. The method of claim 9, wherein at least one reflector of the plurality of reflectors is electrically connected to at least one conductive feature of the plurality of conductive features.

12. The method of claim 9, wherein each reflector of the plurality of reflectors overlaps a respective grating coupler of the plurality of grating couplers.

13. The method of claim 12, wherein each reflector of the plurality of reflectors is a different vertical distance from the respectively overlapping grating coupler of the plurality of grating couplers.

14. The method of claim 9, further comprising attaching a support over the plurality of photonic components, wherein the support comprises an array of microlenses.

15. The method of claim 9, wherein forming the plurality of conductive features comprises forming a first conductive feature of the plurality of conductive features on the first dielectric layer.

16. The method of claim 9, wherein the waveguide is continuous with a first grating coupler of the plurality of grating couplers.

17. A device comprising:
a redistribution structure, comprising:
a plurality of metal lines;
a first metal reflector; and
a second metal reflector;
a plurality of photonic components over the redistribution structure, wherein the plurality of photonic components comprises:
a waveguide;
a first grating coupler, wherein the first grating coupler is optically coupled to the first metal reflector, wherein the first grating coupler is a first distance from the first metal reflector; and
a second grating coupler, wherein the second grating coupler is optically coupled to the second metal reflector, wherein the second grating coupler is a second distance from the second metal reflector that is different than the first distance; and
an electronic die over the plurality of photonic components, wherein the electronic die is electrically connected to the redistribution structure.

18. The device of claim 17, further comprising a support over the electronic die, wherein the support comprises a first lens that is optically coupled to the first metal reflector and a second lens that is optically coupled to the second metal reflector.

19. The device of claim 17, further comprising an interconnect structure between the redistribution structure and the plurality of photonic components, wherein the interconnect structure has a pitch that is smaller than that of the redistribution structure.

20. The device of claim 17, wherein the first grating coupler is configured to couple light having a first range of wavelengths and the second grating coupler is configured to couple light having a second range of wavelengths, wherein the first range and the second range are different.
